(19) United States
(12) Patent Application Publication
(10) Pub. No.: US 2024/0322080 A1
(43) Pub. Date: Sep. 26, 2024

(54) LIGHT EMITTING ELEMENT AND PRODUCTION METHOD THEREFOR

(71) Applicant: TOYODA GOSEI CO., LTD., Kiyosu-shi (JP)

(72) Inventors: Koichi MIZUTANI, Kiyosu-shi (JP); Hideki OMOYA, Kiyosu-shi (JP); Shinichi MATSUI, Kiyosu-shi (JP); Hiroaki MAKINO, Kiyosu-shi (JP)

(21) Appl. No.: 18/608,527

(22) Filed: Mar. 18, 2024

(30) Foreign Application Priority Data
Mar. 24, 2023 (JP) 2023-047893

(51) Int. Cl. H01L 33/38; H01L 33/00; H01L 33/32; H01L 33/62

(52) U.S. Cl. CPC H01L 33/38; H01L 33/007; H01L 33/0095; H01L 33/32; H01L 33/62; H01L 2933/0016; H01L 2933/0066

(57) ABSTRACT

A method for producing a light emitting element, includes: stacking an n layer, a light emitting layer, and a p layer in this order, on a substrate; forming a hole having a depth reaching the n layer at a predetermined region of a surface of the p layer; forming, over the p layer, a p electrode having a Ru layer in contact with the p layer; forming an n electrode as defined herein; and performing a heat treatment as defined herein to reduce a contact resistance of the p electrode and the n electrode and to activate a p-type impurity in the p layer, and a pattern of the hole and a pattern of the p electrode are set such that a proportion of an area of the p electrode to a total area of the hole and the p layer is 70% or more.

### CROSS-REFERENCE TO RELATED APPLICATION

This application is based on and claims priority under 35 USC 119 from Japanese Patent Application No. 2023-047893 filed on Mar. 24, 2023.

### TECHNICAL FIELD

The present invention relates to a light emitting element and a production method therefor.

### BACKGROUND ART

In recent years, the use of ultraviolet LEDs for sterilization and disinfection of water, air, and the like is attracting attention, and research and development toward higher efficiency of ultraviolet LEDs are actively conducted.

In a conventional light emitting element made of a group III nitride semiconductor, ITO or Ni/Au is widely used as a p electrode in contact with a p layer. These materials have a low reflectance in UVC (200 nm to 280 nm). Therefore, in UVC light emitting elements, studies have been made to using Rh or Ru, which has a high reflectance, as a p electrode (JP2020-64955A). In addition, Ti/Al is widely used as an n electrode in contact with the n layer, and it is also known to use V as in JP2003-77862A.

### SUMMARY OF INVENTION

However, the UVC light emitting elements have low power efficiency, and improvements have been required. In order to increase the power efficiency, it is necessary to both improve light extraction efficiency and reduce a forward voltage Vf, which has been difficult to achieve.

The present invention has been made in view of such a background, and an object thereof is to provide a UVC light emitting element having high power efficiency, and a production method therefor.

An aspect of the present invention is directed to a method for producing a light emitting element which includes a group III nitride semiconductor containing Al and has an emission wavelength of 200 nm to 280 nm, comprising:
a semiconductor layer forming step of stacking an n layer, a light emitting layer, and a player in this order, on a substrate;
a hole forming step of forming a hole having a depth reaching the n layer at a predetermined region of a surface of the p layer;
a p electrode forming step of forming, over the p layer, a p electrode having a Ru layer in contact with the p layer;
an n electrode forming step of forming an n electrode over the n layer exposed on a bottom surface of the hole, the n electrode having a V layer that is in contact with the n layer, that has a thickness of 5 nm or more and 15 nm or less, and that comprises V or a metal containing V as a main component, and an Al layer that is on and in contact with the V layer and that comprises Al or a metal containing Al as a main component; and
a heat treatment step of performing a heat treatment at a temperature of 500° C. to 650° C. for 1 to 10 minutes to reduce a contact resistance of the p electrode and the n electrode and to activate a p-type impurity in the p layer, wherein
a pattern of the hole and a pattern of the p electrode are set such that a proportion of an area of the p electrode to a total area of the hole and the p layer is 70% or more.

Another aspect of the present invention is directed to a light emitting element which comprises a group III nitride semiconductor containing Al and has an emission wavelength of 200 nm to 280 nm, the light emitting element comprising:
a substrate;
a semiconductor layer, in which an n layer, a light emitting layer, and a p layer are stacked in this order over the substrate;
a hole provided at a predetermined region of a surface of the p layer and having a depth reaching the n layer;
a p electrode having a Ru layer provided on and in contact with the p layer; and
an n electrode provided over the n layer exposed on a bottom surface of the hole, the n electrode having a first layer that is located in contact with the n layer, that comprises AlNₓ or Al_{y}Ga_{1-y}Nₓ having a higher Al composition than the n layer, and that has a thickness of 1 nm or more and 3 nm or less, and a second layer that is located on and in contact with the first layer, that comprises a metal mainly containing Al and containing V, and that has a thickness of 50 nm or more and 500 nm or less, wherein
a pattern of the hole and a pattern of the p electrode are set such that a proportion of an area of the p electrode to a total area of the hole and the player is 70% or more.

According to the above aspects, when the area of the p electrode made of Ru is increased, it is possible to increase reflection of ultraviolet rays by the p electrode and improve the light extraction efficiency. In addition, both the p electrode and the n electrode have low contact resistance and the forward voltage can be reduced. Therefore, the power efficiency of the UVC light emitting element can be improved.

### BRIEF DESCRIPTION OF DRAWINGS

FIG. 1 is a diagram showing a configuration of a light emitting element according to an embodiment, and is a cross-sectional view perpendicular to a substrate.

FIG. 2 is a diagram showing a plane pattern of an electrode.

FIG. 3 is a diagram showing a process for producing the light emitting element according to the embodiment.

FIG. 4 is a diagram showing the process for producing the light emitting element according to the embodiment.

FIG. 5 is a diagram showing the process for producing the light emitting element according to the embodiment.

FIG. 6 is a diagram showing the process for producing the light emitting element according to the embodiment.

FIG. 7 is a diagram showing the process for producing the light emitting element according to the embodiment.

FIG. 8 is a diagram showing the process for producing the light emitting element according to the embodiment.

FIG. 9 is a diagram showing the process for producing the light emitting element according to the embodiment.

FIG. 10 is a diagram showing the process for producing the light emitting element according to the embodiment.

FIG. 11 is a graph showing I-V characteristics of light emitting elements.

FIG. 12 is a graph (scatter diagram) showing emission wavelengths and power efficiency of light emitting elements.

FIG. 13 is a diagram showing an electrode pattern according to a first modification.

FIG. 14 is a diagram showing a configuration of a light emitting element according to a second modification of the embodiment, and is a cross-sectional view perpendicular to a substrate.

FIG. 15 is a diagram showing an electrode pattern according to the second modification.

### DETAILED DESCRIPTION OF THE INVENTION

A method for producing a light emitting element according to the present invention is a method for producing a light emitting element which includes a group III nitride semiconductor containing Al and has an emission wavelength of 200 nm to 280 nm. The method includes: a semiconductor layer forming step of stacking an n layer, a light emitting layer, and a player in this order, on a substrate; a hole forming step of forming a hole having a depth reaching the n layer in a predetermined region on a surface of the p layer; a p electrode forming step of forming, on the p layer, a p electrode having a Ru layer in contact with the p layer; an n electrode forming step of forming an n electrode on the n layer exposed on a bottom surface of the hole, the n electrode having a V layer that is in contact with the n layer, that has a thickness of 5 nm or more and 15 nm or less, and that contains V or a metal containing V as a main component, and an Al layer that is on and in contact with the V layer and contains Al or a metal containing Al as a main component; and a heat treatment step of performing a heat treatment at a temperature of 500° C. to 650° C. for 1 to 10 minutes to reduce contact resistance of the p electrode and the n electrode and to activate a p-type impurity in the player. A pattern of the hole and a pattern of the p electrode are set such that a proportion of an area of the p electrode to a total area of the hole and the p layer is 70% or more.

The hole may be formed at plural locations, an arrangement pattern of the holes may be a square lattice, an equilateral triangular lattice, or a honeycomb shape, and the n electrode may be formed on a bottom surface of each hole.

The method may further includes: a pn electrode forming step of forming a first pn electrode and a second pn electrode on the p electrode and the n electrode, respectively, after the heat treatment step; a protective film forming step of forming a protective film, which is an insulator, to cover an entire upper surface of the element; and a pad electrode forming step of providing holes at predetermined positions of the protective film, and forming, over the protective film, a p pad electrode connected to the first pn electrode via one of the holes, and forming an n pad electrode connected to the second pn electrode via other of the holes and spaced apart from the p pad electrode.

The light emitting element is made of a group III nitride semiconductor and has an emission wavelength of 200 nm to 280 nm. The light emitting element includes: a substrate; a semiconductor layer, in which an n layer, a light emitting layer, and a p layer are stacked in this order, on a substrate; a hole provided in a predetermined region on a surface of the p layer and having a depth reaching the n layer; a p electrode having a Ru layer provided on and in contact with the p layer; and an n electrode provided on the n layer exposed on a bottom surface of the hole, the n electrode having a first layer that is located in contact with the n layer, that is made of AlNₓ or Al_{y}Ga_{1-y}Nₓ having a higher Al composition than the n layer, and that has a thickness of 1 nm or more and 3 nm or less, and a second layer that is located in contact with the first layer, that is made of a metal mainly containing Al and containing V, and that has a thickness of 50 nm or more and 500 nm or less. A pattern of the hole and a pattern of the p electrode are set such that a proportion of an area of the p electrode to a total area of the hole and the p layer is 70% or more.

The hole may be formed in plural, an arrangement pattern of the holes may be a lattice, and the n electrode may be formed on a bottom surface of each hole.

The light emitting element may further includes: a first pn electrode and a second pn electrode provided on the p electrode and the n electrode, respectively; a protective film, which is an insulator, configured to cover an entire upper surface of the element; a p pad electrode provided on the protective film and connected to the first pn electrode via a hole provided in the protective film; and an n pad electrode provided on the protective film, connected to the second pn electrode via a hole provided in the protective film, and spaced apart from the p pad electrode.

### Embodiment

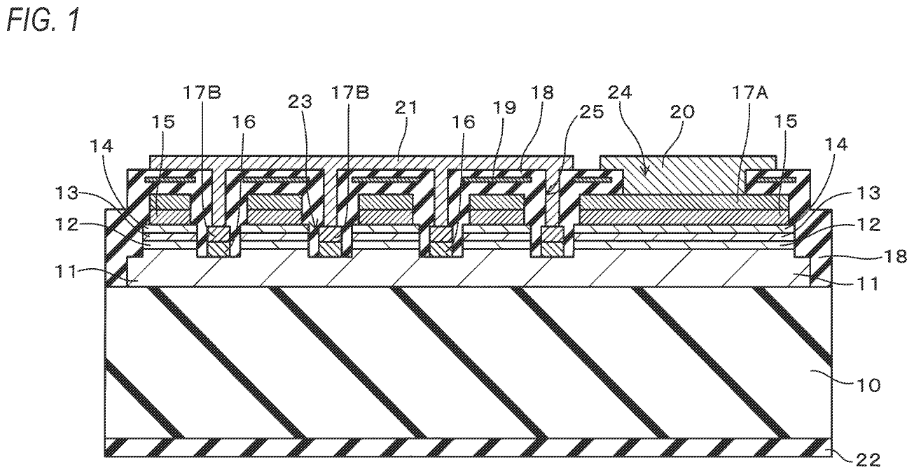

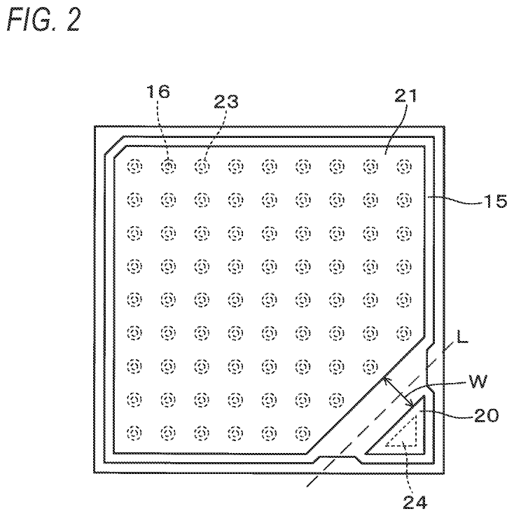

FIG. 1 is a diagram showing a configuration of a light emitting element according to an embodiment, and is a cross-sectional view perpendicular to a substrate. FIG. 2 is a diagram showing a plane pattern of an electrode of the light emitting element according to the embodiment. The light emitting element according to the embodiment is a flip-chip type ultraviolet light emitting element, and has an emission wavelength of UVC, for example, 200 nm to 280 nm.

### 1. Configuration of Light Emitting Element

As shown in FIG. 1, the light emitting element according to the embodiment includes a substrate 10, an n layer 11, a light emitting layer 12, an electron blocking layer 13, a p layer 14, a p electrode 15, n electrodes 16, pn electrodes 17A and 17B, a protective film 18, a reflective film 19, a p pad electrode 20, an n pad electrode 21, and an antireflection film 22. Hereinafter, each configuration will be described.

The substrate 10 is a substrate made of sapphire and having a c plane as a main surface. Other than sapphire, any material may be used as long as the material has a high transmittance with respect to the emission wavelength and can grow a group III nitride semiconductor.

The antireflection film 22 is provided on a back surface (a surface opposite to the n layer 11, a light extraction side) of the substrate 10. By providing the antireflection film 22, it is possible to prevent ultraviolet rays from being reflected on the back surface of the substrate 10 and returning to an element side, thereby improving light extraction. The antireflection film 22 is, for example, SiO₂ having a thickness of ¼ of the emission wavelength.

The n layer 11 is located on the substrate 10 with a buffer layer (not shown) interposed therebetween. The n layer 11 is made of n-AlGaN. An n-type impurity is Si, and a Si concentration is 5×10¹⁸/cm³ to 5×10¹⁹/cm³. The n layer 11 may include a plurality of layers.

The light emitting layer 12 is located on the n layer 11. The light emitting layer 12 has an MQW structure in which a well layer and a barrier layer are alternately and repeatedly stacked. The number of repetitions is, for example, 2 to 5. The well layer is made of AlGaN, and an Al composition thereof is set according to a desired emission wavelength. The barrier layer is made of AlGaN having an Al composition higher than that of the well layer. AlGaInN having band gap energy larger than that of the well layer may also be used. The light emitting layer 12 may have an SQW structure.

The electron blocking layer 13 is located on the light emitting layer 12. The electron blocking layer 13 is made of p-AlGaN having an Al composition ratio higher than that of the barrier layer of the light emitting layer 12. The electron blocking layer 13 prevents electrons injected from the n electrode 16 from passing beyond the light emitting layer 12 and diffusing toward the p layer 14.

The p layer 14 is located on the electron blocking layer 13. The p layer 14 is made of p-AlGaN. In the light emitting element according to the embodiment, all semiconductor layers from the n layer 11 to the p layer 14 are made of AlGaN, and accordingly absorption of ultraviolet rays by the semiconductor layers is prevented. The Al composition in the p layer 14 is, for example, 5% to 80%. A p-type impurity is Mg. A Mg concentration is 1×10¹⁹/cm³ or more. The p layer 14 may include a plurality of layers having different Al compositions and Mg concentrations. In this case, a layer in contact with the p electrode 15 is made of p-AlGaN having an Al composition of 5% to 80%. The p layer 14 is not limited to AlGaN, and may be made of a group III nitride semiconductor containing Al, and may be made of AlGaInN.

A hole 23 having a depth reaching the n layer 11 is formed in a partial region on a surface of the p layer 14. The hole 23 is dot-shaped, and a plurality of holes 23 are arranged in a lattice pattern (see FIG. 2). However, the hole 23 is not provided in a region corresponding to a lower part of the p electrode 15. The n layer 11 is exposed on a bottom surface of the hole 23. When the holes 23 for exposing the n layer 11 are formed in a dot-shaped arrangement pattern, a reduction in a light emitting area (an area of the p layer 14) due to the holes 23 is reduced as much as possible while in-plane light emission is ensured, and a light output is improved.

A plane pattern of each hole 23 is, for example, a circle. Alternatively, a polygon such as a regular hexagonal shape may be used. In the case of a regular hexagonal shape, a side surface of the hole 23 is preferably an m plane. The arrangement pattern of the holes 23 is an equilateral triangular lattice. In addition, for example, a square lattice or a honeycomb-shaped pattern may be used.

The p electrode 15 is provided on the p layer 14. The p electrode 15 is provided on the surface of the p layer 14 except for a region where the hole 23 is not provided and the vicinity of edges of the p layer 14 (see FIG. 2), thereby ensuring a wide light emitting area. The p electrode 15 is a reflective electrode that increases light extraction efficiency by reflecting ultraviolet rays emitted from the light emitting layer 12 toward the substrate 10. A material of the p electrode 15 is Ru. An alloy containing Al as a main component may also be used. Ru has a high reflectance in UVC and low contact resistance to the player 14 made of p-AlGaN, and is thus suitable as the p electrode 15 in a UVC light emitting element.

A proportion of an area of the p electrode 15 to an area of an upper surface of the element (a total area of the holes 23 and the p layer 14) is 70% or more. Plane patterns of the holes 23 and the p electrode 15 are set to satisfy the above. For example, a diameter, the number of arrays, and an arrangement interval of the holes 23 are adjusted. When the area of the p electrode 15 made of Ru is increased, it is possible to increase reflection of ultraviolet rays by the p electrode 15 and improve the light extraction efficiency. It is more preferably 75% or more. The n electrode 16 is provided on the n layer 11 exposed on the bottom surface of each hole 23. Therefore, the n electrodes 16 also have a dot-shaped arrangement pattern (see FIG. 2). A material of the n electrode 16 is a V/Al/Ti structure subjected to a heat treatment. In addition, Ti/Al/Ti can be used. Specifically, the V/Al/Ti structure subjected to a heat treatment has a structure in which a layer made of AlNₓ, a layer made of a metal mainly containing Al and containing V and Ti, and a layer made of Ti are stacked in this order.

The layer made of AlNₓ has a thickness of 1 nm to 3 nm. x is, for example, 0.4 to 0.7. In addition, x may decrease as a distance from the n layer 11 increases in a thickness direction. In this case, an average of x in the thickness direction is 0.4 to 0.7. Ga may be diffused from the n layer 11, and in this case, Al_{y}Ga_{1-y}Nₓ (0.4≤x≤0.7) having a higher Al composition ratio than the n layer 11 is used. When the Al composition ratio in the n layer 11 is a, a<y≤1. y is, for example, 0.7 or more. In this case, x may also decrease as the distance from the n layer 11 increases in the thickness direction, and y may increase as the distance from the n layer 11 increases in the thickness direction.

The layer made of a metal mainly containing Al and containing V and Ti has a thickness of 50 nm to 500 nm. The ratio of Al, V, and Ti is, for example, 50 mol % to 85 mol % for Al, 5 mol % to 20 mol % for V, and 10 mol % to 30 mol % for Ti.

In the n electrode 16 having the above structure, the contact resistance to the n layer 11 is reduced. For example, the contact resistance of the n electrode 16 to the n layer 11 is 4×10⁻⁴ Ω·cm² or less. A reason for this is considered to be, firstly, that the layer made of AlNₓ functions as a good contact layer for the n layer 11. Secondly, it is considered that nitrogen vacancies are generated in a surface of the n layer 11, and the contact resistance is reduced because of being n-type.

The layer made of Ti is provided as a cover to prevent Al in the n electrode 16 from evaporating during alloying. In addition to Ti, TiN, Ni, Pt, Au, or the like can be used.

The pn electrodes 17A and 17B are provided on the p electrode 15 and the n electrode 16, respectively. A plane pattern of the pn electrode 17A is the same as the plane pattern of the p electrode 15. A plane pattern of the pn electrode 17B is the same as the plane pattern of the n electrode 16, and is a pattern in which a plurality of dots are arranged. A material of the pn electrodes 17A and 17B is, for example, Ti/Ni/Au/Al.

The protective film 18 is provided to cover the entire upper surface of the element. That is, it is provided continuously on side surfaces and surfaces of the p electrode 15 and the n electrode 16, surfaces and side surfaces of the semiconductor layers, side surfaces of an element isolation groove 26, and insides of the holes 23.

The protective film 18 is an insulator, for example SiO₂. In addition, SiN, Al₂O₃, TiO₂, and AlN, can be used. The protective film 18 may be obtained by stacking a plurality of materials.

The reflective film 19 made of Al is provided in the protective film 18. The reflective film 19 is entirely provided except for regions where holes 24 and 25, which will be described later, are present. Light is reflected toward the substrate 10 by the reflective film 19 to improve the light extraction efficiency. In addition, heat dissipation of the protective film 18 is improved. A reason why the reflective film 19 is embedded in the protective film 18 is to prevent migration.

A material of the reflective film 19 is not limited to Al, and may be any material that has a high reflectance in the emission wavelength. An alloy containing mainly Al may be used.

The p pad electrode 20 and the n pad electrode 21 are spaced apart from each other on the protective film 18. The p pad electrode 20 is connected to the pn electrode 17A via the hole 24 formed in the protective film 18. The n pad electrode 21 is connected to the pn electrode 17B via the hole 25 formed in the protective film 18. A material of the p pad electrode 20 and the n pad electrode 21 is, for example, Ti/Pt/Au/AuSn.

For plane patterns of the p pad electrode 20 and the n pad electrode 21, a rectangular pattern slightly inside a rectangular pattern of the element is divided into two by a linear region having a width W along a straight line L forming an angle of 45° with respect to sides of the rectangle at a corner of the rectangle, one part forming an isosceles right triangle pattern is the p pad electrode 20, and the other part (a pentagon with the corner of the rectangle cut off) is the n pad electrode 21.

The angle of the linear region is not limited to 45°, and is preferably close to 45°, and is preferably, for example, 30° to 60°, and more preferably 40° to 50° in order to increase a sum of areas of the p pad electrode 20 and the n pad electrode 21 as much as possible.

The position and the width W of the linear region is preferably set such that the sum of the areas of the p pad electrode 20 and the n pad electrode 21 is 90% or more of the light emitting area (the area of the p electrode 15). Of course, the width W is set to such a width that no short circuit occurs between the p pad electrode 20 and the n pad electrode 21. For example, the width W is 100 μm or more. Further, the p pad electrode 20 has a size that allows good bonding to a sub-mount side. For example, the length of two equal sides of the isosceles right triangle for the p pad electrode 20 is 200 μm or more.

When the plane patterns of the p pad electrode 20 and the n pad electrode 21 are set as described above, the sum of the areas of the p pad electrode 20 and the n pad electrode 21 can be increased, and the heat dissipation performance can be improved.

In the above light emitting element according to the embodiment, Ru is used as the material of the p electrode 15, and the proportion of the area of the p electrode 15 to the area of the upper surface of the element is 70% or more, and accordingly, the light extraction is improved. In addition, both the p electrode 15 and the n electrode 16 have low contact resistance and a forward voltage can be reduced. Therefore, the power efficiency of the light emitting element can be improved.

### 2. Process for Producing Light Emitting Element

A process for producing the light emitting element according to the embodiment will be described with reference to the drawings.

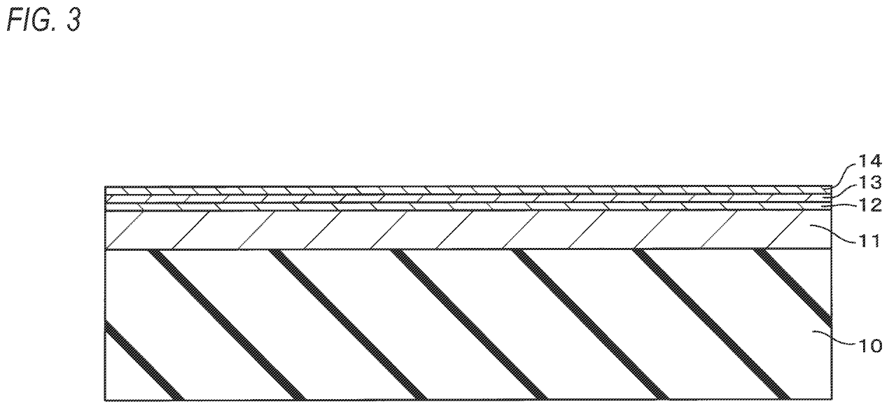

First, the substrate 10 made of sapphire is prepared. Then, the n layer 11, the light emitting layer 12, the electron blocking layer 13, and the p layer 14 are formed in this order on the substrate 10 by a MOCVD method (see FIG. 3).

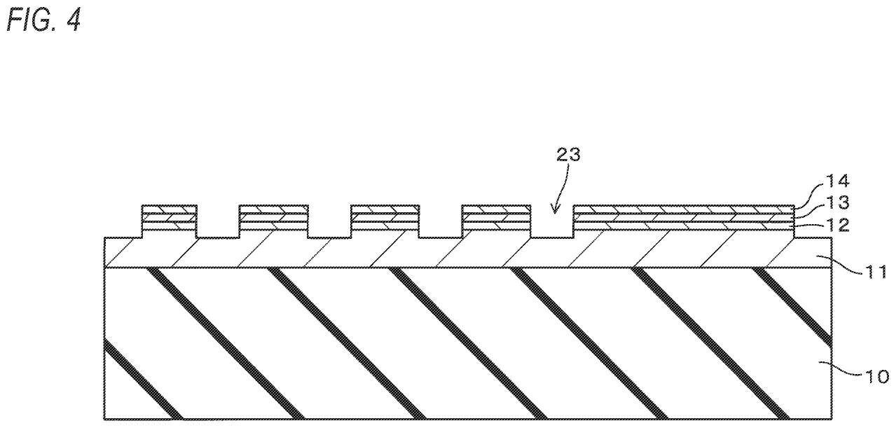

Next, predetermined regions in the p layer 14 are dry-etched to form a plurality of holes 23 having a depth reaching the n layer 11 (see FIG. 4).

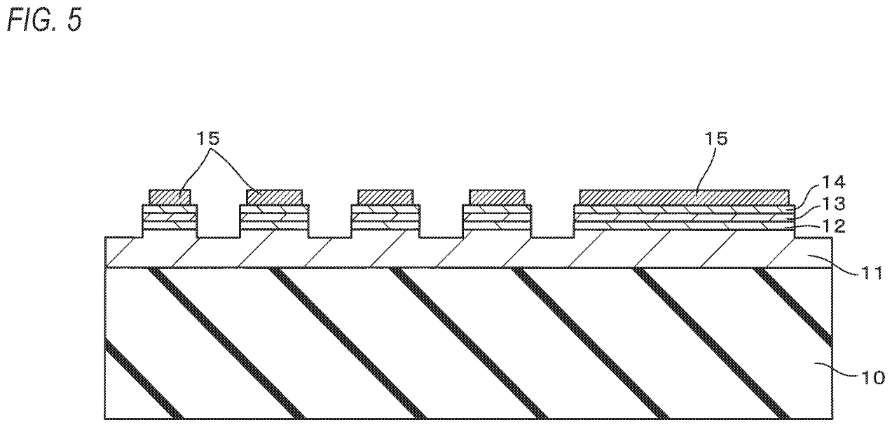

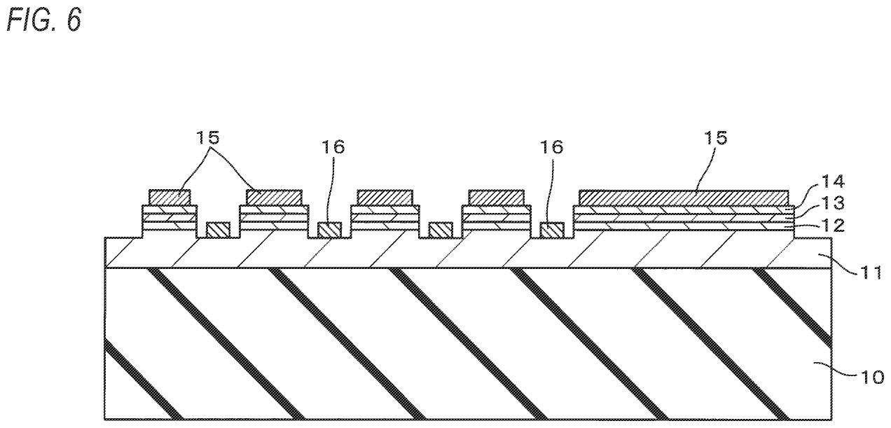

Next, the p electrode 15 is formed on the p layer 14 by sputtering or vapor deposition (see FIG. 5). Next, a V layer, an Al layer, and a Ti layer are stacked in this order on the n layer 11 exposed on the bottom surface of the hole 23 by sputtering or vapor deposition to form the n electrode 16 (see FIG. 6). Although the n electrode 16 may be formed before the p electrode 15, in the embodiment, the p electrode 15 is formed first because it is desired to form the p electrode 15 with the surface of the p layer 14 as clean as possible.

Next, a heat treatment is performed at a temperature of 500° C. to 650° C. for 1 to 10 minutes. The heat treatment is preferably performed under a reduced pressure in an inert gas atmosphere such as nitrogen, for example, at a pressure of 1×10² Pa to 1×10⁴ Pa. The heat treatment temperature is preferably 500° C. to 560° C.

This heat treatment also serves both to activate Mg in the p layer 14 and to reduce the contact resistance of the p electrode 15 and the n electrode 16.

In the embodiment, by using V/Al/Ti as the n electrode 16, the heat treatment temperature is lowered, and the Mg activation treatment of the p layer 14 and the reduction of the contact resistance of the p electrode 15 and the n electrode 16 are shared and performed at the same time, thereby reducing the number of heat treatments. As a result of lowering the heat treatment temperature and reducing the number of heat treatments, deterioration of electrical characteristics of the light emitting element can be prevented.

Here, the n electrode 16 changes to the following structure by the heat treatment. In V/Al/Ti that is the n electrode 16, V diffuses into Al and does not diffuse into the n layer 11 or Ti. As a result of this diffusion, the V layer disappears. In addition, Al in V/Al/Ti reacts with N in the n layer 11, and AlNₓ is formed at an interface between the n layer 11 and the Al layer. Vis considered to act as a catalyst that promotes the reaction between Al and N. As a result of this heat treatment, the structure of the n electrode 16 changes to a three-layer structure including a layer made of AlNₓ, a layer made of a metal mainly containing Al and containing V and Ti, and a layer made of Ti.

By changing the n electrode 16 to such a structure, the contact resistance of the n electrode 16 with respect to the n layer 11 is reduced. The reason is as described above. That is, firstly, it is considered that the layer made of AlNₓ functions as a good contact layer with respect to the n layer 11, and secondly, it is considered that the conversion of the n layer 11 into an n-type is further promoted due to the generation of nitrogen vacancies in the n layer 11 due to the formation of AlNₓ.

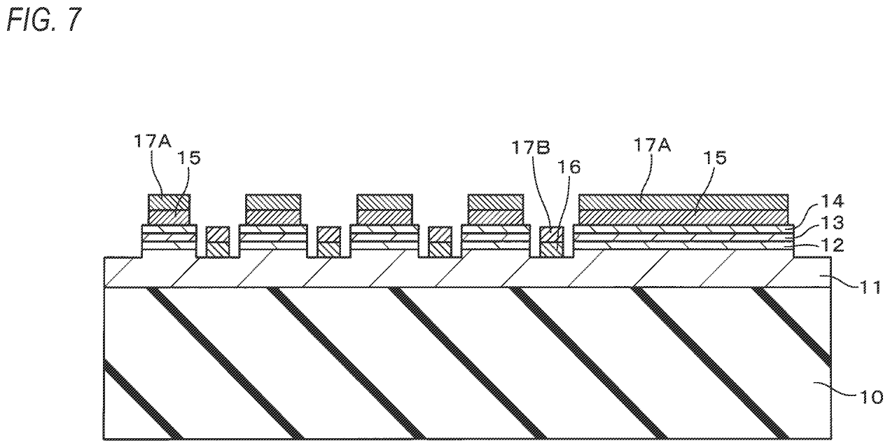

Next, the pn electrodes 17A and 17B are formed on the p electrode 15 and the n electrode 16 respectively by sputtering or vapor deposition (see FIG. 7).

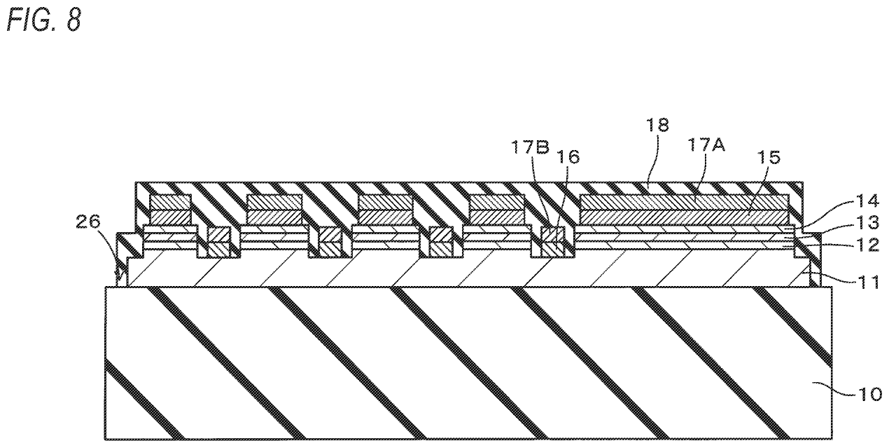

Next, the element isolation groove 26 is formed. The element isolation groove 26 has a depth such that the substrate 10 is exposed. Next, the protective film 18 covering the entire upper surface of the element is formed (see FIG. 8). The protective film 18 is formed by vapor deposition, sputtering, CVD, or the like. Sputtering or CVD is preferred from the viewpoint of denseness of the film.

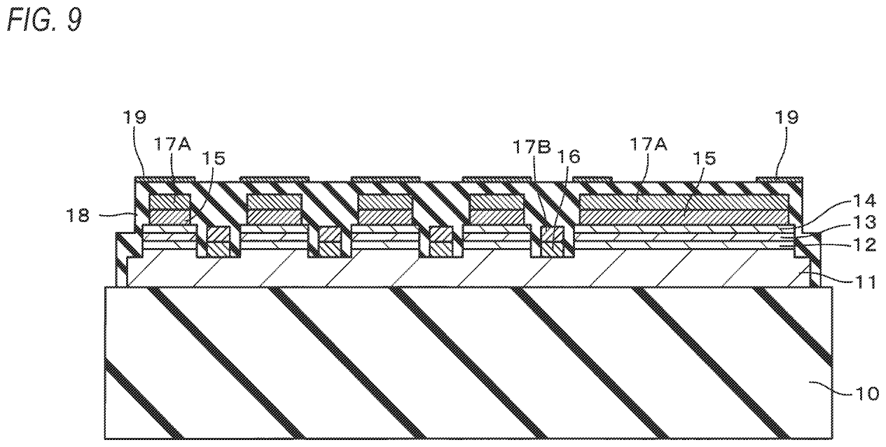

Next, the reflective film 19 made of Al is formed on the protective film 18 in a region excluding the regions where the holes 24 and 25 are to be formed later (see FIG. 9). The reflective film 19 is formed by vapor deposition or sputtering, and patterned by wet etching.

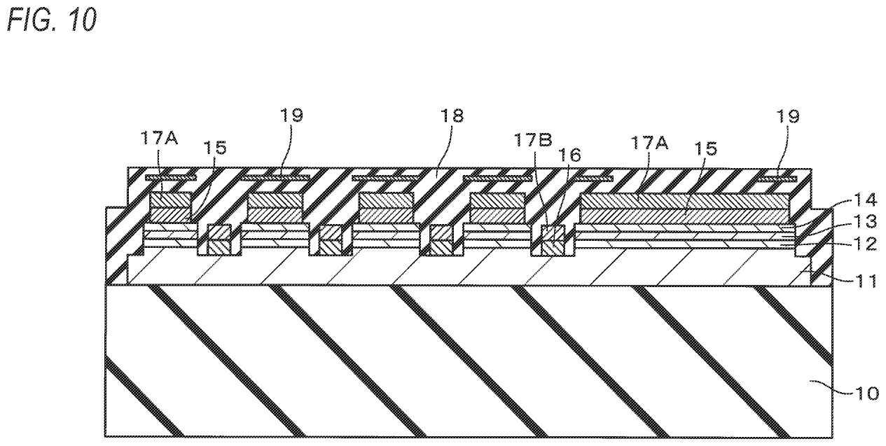

Next, the protective film 18 is formed again on the protective film 18 and the reflective film 19 (see FIG. 10). Accordingly, a structure in which the reflective film 19 is embedded in the protective film 18 is obtained. Note that, it is preferable that the protective film 18 is not formed on a bottom surface of the element isolation groove 26 and the protective film 18 is separated for each element. This is to prevent a force from being applied to the protective film 18 or a change in stress of the protective film 18 when the protective film 18 is divided for each element.

Next, a predetermined region on the protective film 18 is dry-etched to form the hole 24 and the hole 25 reaching the pn electrodes 17A and 17B. Then, the p pad electrode 20 and the n pad electrode 21 are formed on the protective film 18, the p pad electrode 20 is connected to the pn electrode 17A via the hole 24, and the n pad electrode 21 is connected to the pn electrode 17B via the hole 25. The patterns of the p pad electrode 20 and the n pad electrode 21 are as shown in FIG. 2. The p pad electrode 20 and the n pad electrode 21 are formed by vapor deposition or sputtering, and patterned by lift-off. Next, the antireflection film 22 is formed on the back surface of the substrate 10. Next, the substrate 10 is divided into individual elements. With the above, the light emitting element according to the embodiment shown in FIG. 1 is produced.

### 3. Experiment Results

Various experiment results according to the embodiment will be described.

### Experiment 1

The light emitting element according to the embodiment having an emission wavelength of 275 nm and including the p electrode 15 made of Ru was prepared. For comparison, a light emitting element including the p electrode 15 made of Rh instead of Ru was also prepared.

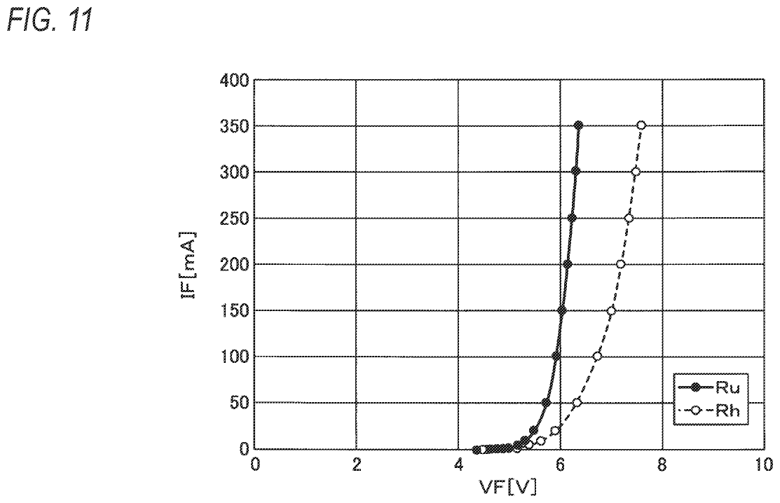

FIG. 11 is a graph showing I-V characteristics of the light emitting elements. As shown in FIG. 11, it has been found that a drive voltage can be lower in a case where Ru is used as the p electrode 15 than a case where Rh is used as the p electrode 15. This is because Ru has contact resistance to the p layer 14 lower than that of Rh.

### Experiment 2

A plurality of light emitting elements according to the embodiment having the composition of the light emitting layer 12 set to have an emission wavelength of 275 nm and including the p electrode 15 made of Ru were prepared. For comparison, a plurality of light emitting elements in which the material of the p electrode 15 was changed from Ru to Rh were also prepared.

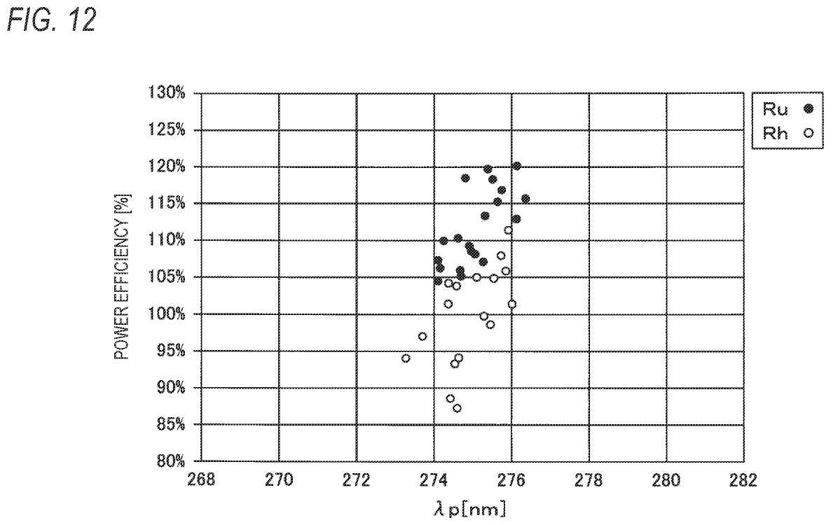

FIG. 12 is a graph (scatter diagram) showing emission wavelengths and power efficiency of the light emitting elements. The power efficiency is a value normalized by setting average power efficiency when the p electrode 15 is made of Rh as 100%. As shown in FIG. 12, it has been found that the power efficiency tends to be higher in a case where Ru is used as the p electrode 15 than a case where Rh is used as the p electrode 15. This is considered to be because, although both Ru and Rh have a high ultraviolet reflectance, the contact resistance of Ru is lower than that of Rh. It is also found that a variation in power efficiency is smaller for Ru than for Rh. As a result of Experiments 1 and 2, it is found that Ru is more preferred than Rh as the p electrode 15 of the UVC light emitting element.

### 4. Modifications of Embodiment

Light emitting elements according to various modifications of the embodiment will be described.

### First Modification

The electrode pattern shown in the embodiment is an example, and other patterns may be used as long as the proportion of the area of the p electrode 15 to the area of the upper surface of the element is 70% or more. For example, a pattern as in the following first modification may be used.

A light emitting element according to the first modification of the embodiment has the electrode pattern changed as follows: a p electrode 115, an n electrode 116, a p pad electrode 120, an n pad electrode 121, and a hole 123 are provided instead of the p electrode 15, the n electrode 16, the p pad electrode 120, the n pad electrode 121, and the hole 23 in the embodiment.

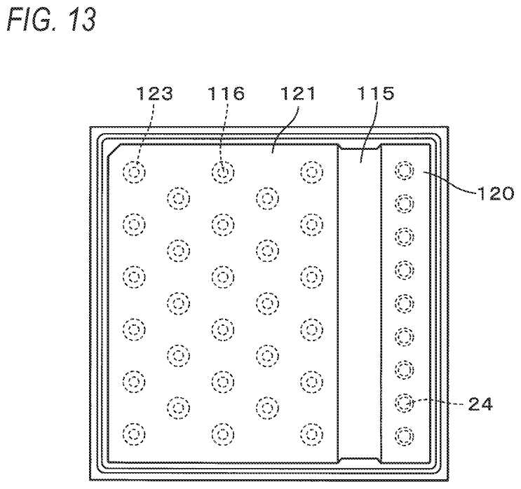

FIG. 13 is a diagram showing the electrode pattern of the light emitting element according to the first modification of the embodiment. As shown in FIG. 13, the p pad electrode 120 and the n pad electrode 121 have patterns in which a pattern slightly inside a rectangular pattern of the element is divided into two by a band-shaped linear region along a straight line parallel to sides of the rectangle. The linear region is located near one side of the rectangle, and among the two patterns obtained by division by the linear region, the one having a smaller area is the p pad electrode 120, and the one having a larger area is the n pad electrode 121.

The hole 123 provided instead of the hole 23 is located below the n pad electrode 121, and a plurality of holes 123 are arranged in a triangular lattice. The hole 123 is not arranged in a region below the p pad electrode 120. The n electrode 116 and the pn electrode 17B are provided in this order on a bottom surface of the hole 123, and the pn electrode 17B and the n pad electrode 121 are connected to each other via the hole 25 made in the protective film 18. Note that, a pattern of the hole 25 is almost the same as a pattern of the n electrode 116, and is not shown in FIG. 13.

The p electrode 115 provided instead of the p electrode 15 has a pattern obtained by removing the holes 123 from a pattern of the p layer 14. The pn electrode 17A is provided on the p electrode 115, and the pn electrode 17A and the p pad electrode 120 are connected to each other via the hole 24. The hole 24 connecting the pn electrode 17A and the p pad electrode 120 is circular, and a plurality of holes are arranged along the side of the rectangle. Note that, a pattern of a circle outside the circle of the hole 24 indicates a boundary of the reflective film 19.

### Second Modification

A light emitting element according to a second modification of the embodiment is the same as the light emitting element according to the embodiment except that the electrode structure and the electrode pattern are changed.

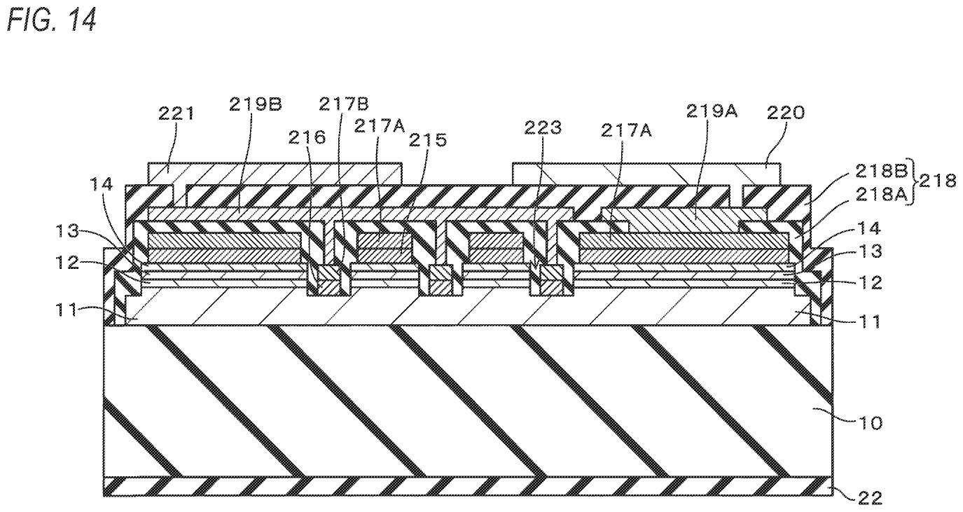

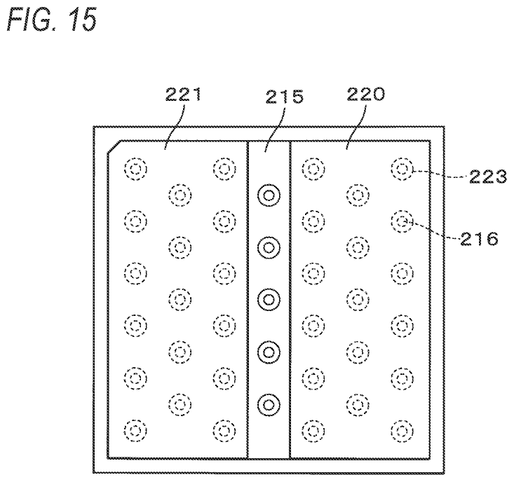

FIG. 14 is a diagram showing a configuration of the light emitting element according to the second modification of the embodiment, and is a cross-sectional view perpendicular to main surface of a substrate. FIG. 15 is a diagram showing the electrode pattern of the light emitting element according to the second modification of the embodiment. FIG. 15 shows a plane pattern of a p electrode 215, an n electrode 216, a p pad electrode 220, and an n pad electrode 221.

As shown in FIG. 14 and FIG. 15, a hole 223 is provided instead of the hole 23. The holes 223 are circular and arranged in an equilateral triangular lattice. The n electrode 216 and an pn electrode 217B are provided in this order on a bottom surface of the hole 223. Unlike the case in FIG. 2 or FIG. 13, the holes 223 are arranged all over the surface, and the holes 223 are also provided below the p pad electrode 220. The p electrode 215 is formed in a pattern obtained by excluding the region of the hole 223 from the rectangular pattern of the p layer 14. In addition, a pn electrode 217A is provided on the p electrode 215 in the same plane pattern as the p electrode 215.

In addition, a protective film 218 is provided instead of the protective film 18. The protective film 218 has a structure in which a first protective film 218A and a second protective film 218B are stacked in this order. The first protective film 218A and the second protective film 218B may be made of the same material or different materials.

Middle electrodes 219A and 219B are separately provided between the first protective film 218A and the second protective film 218B. Note that, in FIG. 15, the middle electrodes 219A and 219B are not shown. The middle electrode 219A is connected to the p electrode 215 via a hole provided in the first protective film 218A. The middle electrode 219B is connected to each dot-shaped n electrode 216 via a hole provided in the first protective film 218A. These holes are also not shown in FIG. 15.

The p pad electrode 220 and the n pad electrode 221 are spaced apart from each other on the protective film 218B. The p pad electrode 220 is connected to the middle electrode 219A via a hole made in the second protective film 218B. The n pad electrode 221 is connected to the middle electrode 219B via a hole made in the second protective film 218B. These holes are also not shown in FIG. 15. As shown in FIG. 15, the p pad electrode 220 and the n pad electrode 221 have patterns in which a pattern slightly inside a rectangular pattern of the element is equally divided into two by a band-shaped linear region along a straight line parallel to sides of the rectangle.

In the second modification, the holes 223 can be arranged over the entire surface, and in-plane uniformity of light emission can be improved. In addition, the middle electrode 219A is interposed between the p electrode 215 and the p pad electrode 220, and the middle electrode 219B is interposed between the n electrode 216 and the n pad electrode 221, and accordingly, the patterns of the p pad electrode 220 and the n pad electrode 221 can be freely set.

### REFERENCE SIGNS LIST

10: substrate
11: n layer
12: light emitting layer
13: electron blocking layer
14: p layer
15: p electrode
16: n electrode
17A, 17B: pn electrode
18: protective film
19: reflective film
20: p pad electrode
21: n pad electrode

What is claimed is:

1. A method for producing a light emitting element which includes a group III nitride semiconductor containing Al and has an emission wavelength of 200 nm to 280 nm, comprising:
stacking an n layer, a light emitting layer, and a p layer in this order, over a substrate;
forming a hole having a depth reaching the n layer at a predetermined region of a surface of the p layer;
forming, over the player, a p electrode having a Ru layer in contact with the p layer;
forming an n electrode over the n layer exposed on a bottom surface of the hole, the n electrode having a V layer that is in contact with the n layer, that has a thickness of 5 nm or more and 15 nm or less, and that comprises V or a metal containing V as a main component, and an Al layer that is on and in contact with the V layer and that comprises Al or a metal containing Al as a main component; and
performing a heat treatment at a temperature of 500° C. to 650° C. for 1 to 10 minutes to reduce a contact resistance of the p electrode and the n electrode and to activate a p-type impurity in the p layer, wherein
a pattern of the hole and a pattern of the p electrode are set such that a proportion of an area of the p electrode to a total area of the hole and the p layer is 70% or more.

2. The method for producing a light emitting element according to claim 1, wherein the hole is formed at plural locations, an arrangement pattern of the holes is a square lattice, an equilateral triangular lattice, or a honeycomb shape, and the n electrode is formed on a bottom surface of each of the holes.

3. The method for producing a light emitting element according to claim 1, further comprising:
forming a first pn electrode and a second pn electrode over the p electrode and over the n electrode, respectively, after the heat treatment;
forming a protective film, which is an insulator, to cover an entire upper surface of the element; and
providing holes at predetermined positions of the protective film, and forming, over the protective film, a p pad electrode that is connected to the first pn electrode via one of the holes provided at the predetermined positions of the protective film, and an n pad electrode that is connected to the second pn electrode via other of the holes provided at the predetermined positions of the protective film and is spaced apart from the p pad electrode.

4. The method for producing a light emitting element according to claim 2, further comprising:
forming a first pn electrode and a second pn electrode over the p electrode and over the n electrode, respectively, after the heat treatment;
forming a protective film, which is an insulator, to cover an entire upper surface of the element; and
providing holes at predetermined positions of the protective film, and forming, over the protective film, a p pad electrode that is connected to the first pn electrode via one of the holes provided at the predetermined positions of the protective film, and an n pad electrode that is connected to the second pn electrode via other of the holes provided at the predetermined positions of the protective film and is spaced apart from the p pad electrode.

5. A light emitting element which comprises a group III nitride semiconductor containing Al and has an emission wavelength of 200 nm to 280 nm, the light emitting element comprising:
a substrate;
a semiconductor layer, in which an n layer, a light emitting layer, and a p layer are stacked in this order over the substrate;
a hole provided at a predetermined region of a surface of the p layer and having a depth reaching the n layer;
a p electrode having a Ru layer provided on and in contact with the p layer; and
an n electrode provided over the n layer exposed on a bottom surface of the hole, the n electrode having a first layer that is located in contact with the n layer, that comprises AlNₓ or Al_{y}Ga_{1-y}Nₓ having a higher Al composition than the n layer, and that has a thickness of 1 nm or more and 3 nm or less, and a second layer that is located on and in contact with the first layer, that comprises a metal mainly containing Al and containing V, and that has a thickness of 50 nm or more and 500 nm or less, wherein
a pattern of the hole and a pattern of the p electrode are set such that a proportion of an area of the p electrode to a total area of the hole and the p layer is 70% or more.

6. The light emitting element according to claim 5, wherein the hole is formed at plural locations, an arrangement pattern of the holes is a lattice, and the n electrode is formed on a bottom surface of each of the holes.

7. The light emitting element according to claim 5, further comprising:
a first pn electrode and a second pn electrode provided over the p electrode and over the n electrode, respectively;
a protective film which is an insulator and covers an entire upper surface of the element;
a p pad electrode provided over the protective film and connected to the first pn electrode via a hole provided at the protective film; and
an n pad electrode provided over the protective film, connected to the second pn electrode via a hole provided at the protective film, and spaced apart from the p pad electrode.

8. The light emitting element according to claim 6, further comprising:
a first pn electrode and a second pn electrode provided over the p electrode and over the n electrode, respectively;
a protective film which is an insulator and covers an entire upper surface of the element;
a p pad electrode provided over the protective film and connected to the first pn electrode via a hole provided at the protective film; and
an n pad electrode provided over the protective film, connected to the second pn electrode via a hole provided at the protective film, and spaced apart from the p pad electrode.
